(19) United States
(12) Patent Application Publication
(10) Pub. No.: US 2025/0266368 A1
(43) Pub. Date: Aug. 21, 2025

(54) METHOD OF FORMING SEMICONDUCTOR DEVICE, ZERO-LAYER OVERLAY MARK AND METHOD OF FORMING THE SAME

(71) Applicant: United Microelectronics Corp., Hsinchu (TW)

(72) Inventors: Shin-Hung Li, Nantou County (TW); Shan-Shi Huang, Hsinchu City (TW)

(73) Assignee: United Microelectronics Corp., Hsinchu (TW)

(21) Appl. No.: 18/604,507

(22) Filed: Mar. 14, 2024

(30) Foreign Application Priority Data
Feb. 19, 2024 (CN) 202410185212.5

(51) Int. Cl. H01L 23/544; H01L 21/027; H01L 21/762

(52) U.S. Cl. CPC H01L 23/544; H01L 21/0274; H01L 21/76229

(57) ABSTRACT

A method for forming a zero-layer overlay mark includes the following steps. A mask layer is formed on the substrate. The mask layer is patterned to form a plurality of openings exposing the substrate. A thermal oxidation process is performed to oxidize the substrate exposed by the plurality of openings to form a plurality of oxide layers. A thickness of the substrate under the plurality of oxide layers is less than a thickness of the substrate under the mask layer, thereby forming a zero-layer overlay mark.

### CROSS-REFERENCE TO RELATED APPLICATION

This application claims the priority benefit of China application serial no. 202410185212.5, filed on Feb. 19, 2024. The entirety of the above-mentioned patent application is hereby incorporated by reference herein and made a part of this specification.

### BACKGROUND

### Technical Field

This disclosure is related to an integrated circuit and a method of forming the same, and in particular related to a method of forming a semiconductor device, a zero-layer overlay mark and a method of forming the zero-layer overlay mark.

### Description of Related Art

When it comes to semiconductor manufacturing process, normally the most advanced manufacturing process such as 7 nm, 5 nm and 3 nm manufacturing process receives a lot of attention. However, from the perspective of overall industry, there is no need to adopt such advanced manufacturing process for a large number of chips because the OEC cost for 28 nm and 22 nm manufacturing process is relatively cheap and the design cost is also low; and the performance is sufficient for chips such as power supply chips, automotive chips, and MCUs. Before the process of semiconductor devices begins, a zero-layer overlay mark is normally formed in the substrate as an alignment basis for subsequent processes. However, the multiple grooves of the conventional zero-layer overlay mark are completed through an additional etching process.

### SUMMARY

The present disclosure provides a zero-layer overlay mark that may be formed while forming devices in the chip region without requiring an additional etching process.

A method for forming a zero-layer overlay mark according to an embodiment of the disclosure includes the following steps. A mask layer is formed on the substrate. The mask layer is patterned to form a plurality of openings exposing the substrate. A thermal oxidation process is performed to oxidize the substrate exposed by the plurality of openings to form a plurality of oxide layers. A thickness of the substrate under the plurality of oxide layers is less than a thickness of the substrate under the mask layer, thereby forming a zero-layer overlay mark.

A method for forming a semiconductor device according to an embodiment of the present disclosure includes the following steps. A substrate is provided, the substrate includes a chip region and a cutting lane region. A mask layer is formed on the substrate. The mask layer is patterned to form a plurality of first openings exposing the substrate in the cutting lane region, and a second opening is formed to expose the substrate in the chip region. A thermal oxidation process is performed to oxidize the substrate exposed by the plurality of first openings to form a plurality of first oxide layers, and to oxidize the substrate exposed by the second opening to form a second oxide layer, wherein the thickness of the substrate under the plurality of first oxide layers is less than the thickness of the substrate under the mask layer to form an overlay mark. The overlay mark is used as a zero-layer overlay mark to perform multiple ion implantation processes on the substrate in the chip region.

A zero-layer overlay mark in an embodiment of the present disclosure includes: a mask layer and a plurality of oxide layers. The mask layer is on the substrate. The mask layer has a plurality of openings to expose the substrate. A plurality of oxide layers are located in the plurality of openings and extend into the substrate. The thickness of the substrate under the plurality of oxide layers is less than the thickness of the substrate under the mask layer to form a zero-layer overlay mark.

Based on the above, the zero-layer overlay mark according to the embodiment of the present disclosure may be formed simultaneously during the process of forming the metal oxide semiconductor device without the need for an additional etching process. Therefore, the present disclosure may be integrated with the existing manufacturing process and save steps in the manufacturing process.

### BRIEF DESCRIPTION OF THE DRAWINGS

FIG. 1A to FIG. 1G are schematic cross-sectional views of a method for manufacturing a semiconductor device according to an embodiment of the present disclosure.

FIG. 2 is a top view of an overlay mark according to an embodiment of the present disclosure.

### DESCRIPTION OF THE EMBODIMENTS

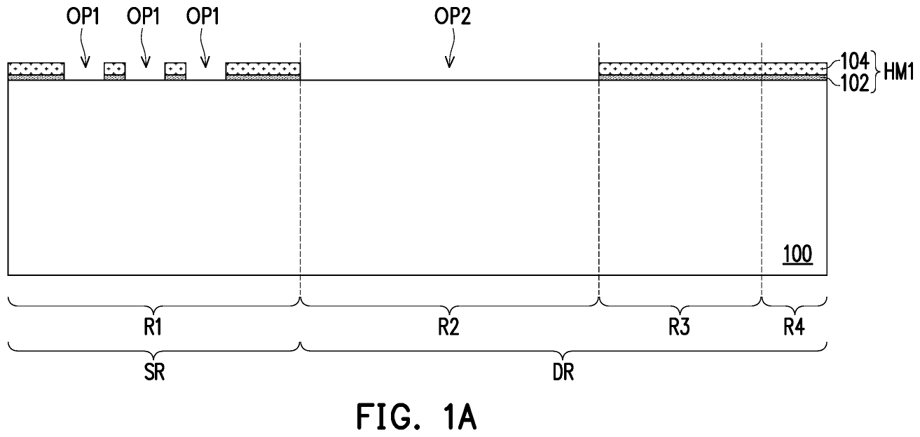

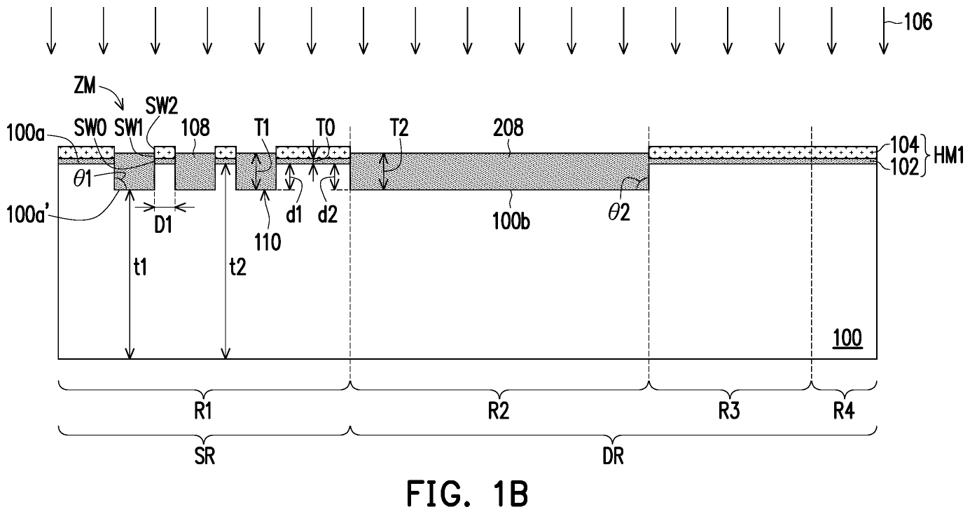

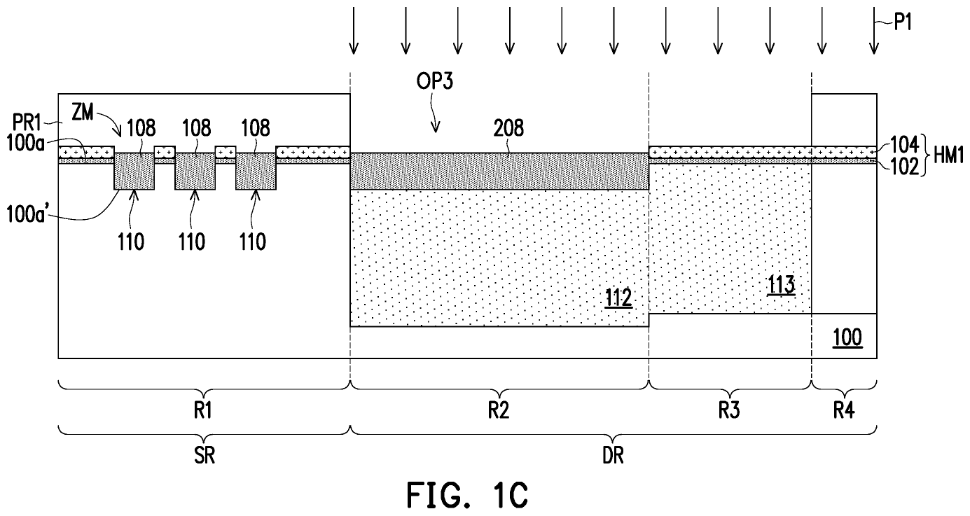

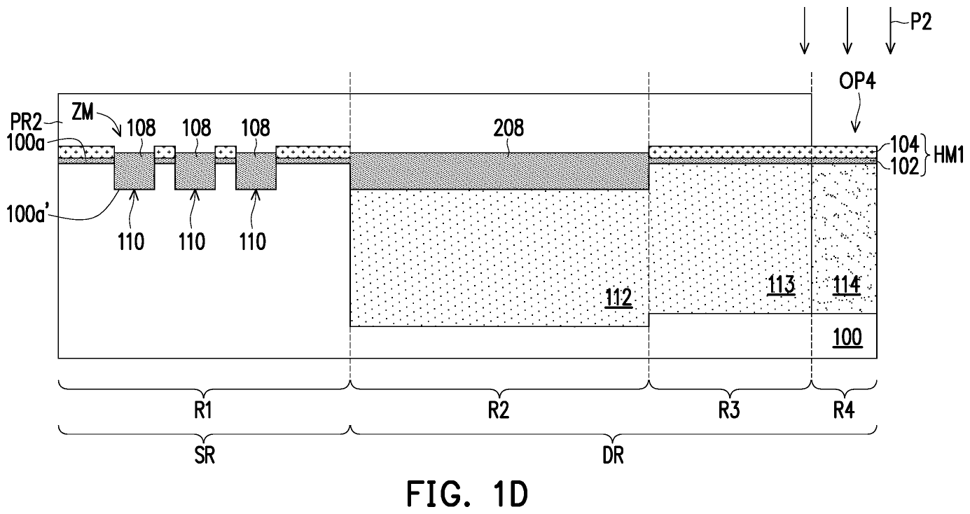

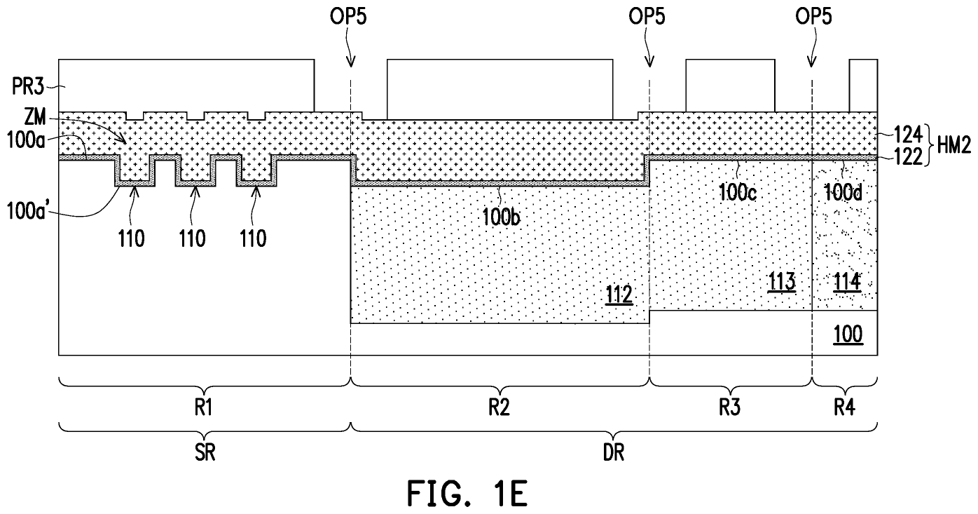

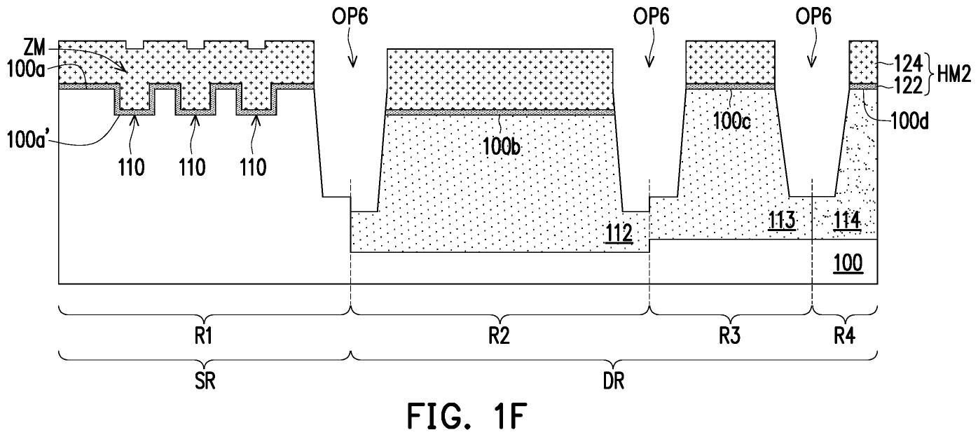

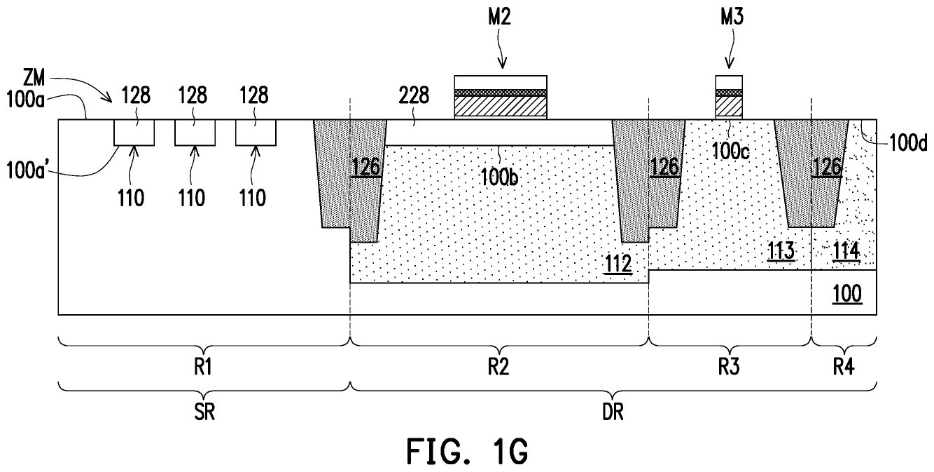

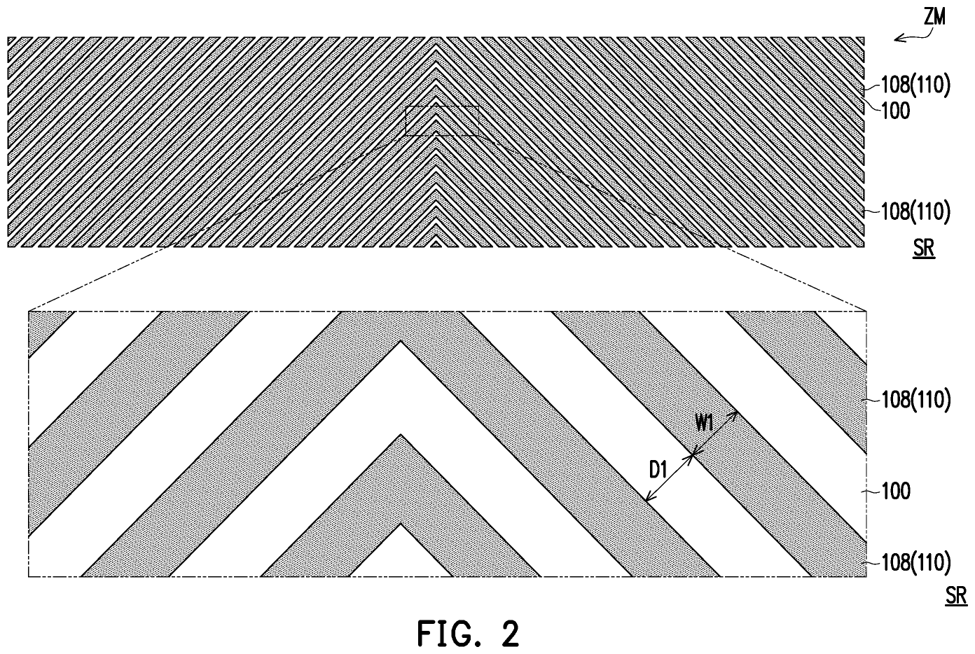

FIG. 1A to FIG. 1G are schematic cross-sectional views of a method for manufacturing a semiconductor device according to an embodiment of the present disclosure. FIG. 2 is a top view of an overlay mark according to an embodiment of the present disclosure.

Referring to FIG. 1A, a substrate 100 is provided. The substrate 100 includes a semiconductor substrate, such as a silicon substrate. The substrate 100 may also be a silicon substrate on an insulating layer. The substrate 100 may include regions R1, R2, R3, and R4. The region R1 is located at, for example, a cutting lane region SR. The regions R2, R3 and R4 are located at, for example, in the chip region DR. In some examples, the regions R2, R3 and R4 are respectively a first conductivity type medium voltage device region, a first conductivity type low voltage device region and a second conductivity type high voltage device region. In other examples, the regions R2, R3 and R4 are respectively a first conductivity type medium voltage device region, a first conductivity type high voltage device region and a second conductivity type high voltage device region. The first conductivity type is, for example, P type; the second conductivity type, for example, is N type. The P-type dopant is, for example, phosphorus or arsenic. The N-type dopant is, for example, boron or boron trifluoride.

Next, a mask layer HM1 is formed on the substrate 100. The mask layer HM1 includes a pad oxide layer 102 and a silicon nitride layer 104. A pad oxide layer 102 is formed on the substrate 100. A silicon nitride layer 104 is formed on the pad oxide layer 102. The pad oxide layer 102 is, for example, silicon oxide, and is formed by, for example, thermal oxidation. The silicon nitride layer 104 is formed by, for example, chemical vapor deposition.

Thereafter, the mask layer HM1 is patterned to form a plurality of openings OP1 and openings OP2. The plurality of openings OP1 and openings OP2 are formed through the same photolithography process and the same etching process. The plurality of openings OP1 expose the surface of the substrate 100 in the region R1. The plurality of openings OP2 expose the surface of the substrate 100 in the region R2. The width of the opening OP1 is less than the width of the opening OP2.

Referring to FIG. 1B, a thermal oxidation process 106 is performed to oxidize the substrate 100 exposed by the plurality of openings OP1 and OP2, so as to form the oxide layer 208 in the region R2 while forming the oxide layer 108 in the region R1, thereby forming an overlay mark ZM.

The oxide layer 208 of the region R2 extends into the substrate 100. The oxide layer 208 has a thickness T2. The surface 100b of the substrate 100 under the oxide layer 208 in the region R2 is lower than the surface 100a of the substrate 100 in the region R1 and has a depth d2.

Regarding the plurality of oxide layers 108 in the region R1, the plurality of oxide layers 108 are formed while the oxide layer 208 is formed. The plurality of oxide layers 108 extend into the substrate 100 to have a thickness T1. The thickness T1 of the plurality of oxide layers 108 is substantially equal to the thickness T2 of the oxide layer 208. The thickness T1 and the thickness T2 are, for example, 400 to 450 angstroms.

The thicknesses T1 and T2 of the plurality of oxide layers 108 and 208 are greater than the thickness T0 of the pad oxide layer 102. The plurality of top surfaces of the plurality of oxide layers 108 and 208 are higher than the top surface of the pad oxide layer 102, and the plurality of bottom surfaces of the plurality of oxide layers 108 and 208 are lower than the bottom surface of the pad oxide layer 102. The plurality of top surfaces of the plurality of oxide layers 108 and 208 are higher than the bottom surface of the silicon nitride layer 104, and the plurality of top surfaces of the plurality of oxide layers 108 and 208 are lower than the top surface of the silicon nitride layer 104. The plurality of oxide layers 108 and 208 are in contact with the sidewall sw0 of the pad oxide layer 102 and part of the sidewall sw1 (i.e., the lower sidewall) of the silicon nitride layer 104. Another part of the sidewall sw2 (i.e., the upper sidewall) of the silicon nitride layer 104 is adjacent to the plurality of oxide layers 108 but is not covered by the plurality of oxide layers 108. The height of the side wall sw2 is, for example, 100 angstroms to 140 angstroms.

The height of the surface 100a′ of the substrate 100 under the plurality of oxide layers 108 in the region R1 is substantially equal to the height of the surface 100b of the substrate 100 under the oxide layer 208 in the region R2. The height of the surface 100a′ of the substrate 100 under the plurality of oxide layers 108 in the region R1 is lower than the height of the surface 100a of the substrate 100 under the mask layer HM1, so that the substrate 100 in the region R1 has a plurality of grooves 110 to form an uneven surface. The groove 110 has a depth d1 that is deep enough. The depth d1 is substantially equal to the depth d2. The depth d1 and the depth d2 are, for example, 180 angstroms to 220 angstroms. In an embodiment of the present disclosure, the groove 110 is formed by itself while forming the plurality of oxide layers 108 and 208 instead of being formed through an etching process.

In an embodiment of the present disclosure, the thickness t1 of the substrate 100 under the plurality of oxide layers 108 in the region R1 is less than the thickness t2 of the substrate 100 under the mask layer HM1. The difference between the thickness t2 and the thickness t1 is equal to the depth d1. Since the substrate 100 in the region R1 has different thicknesses t1 and t2, the refractive index generated after the light is incident is different, so the substrate 100 may serve as the overlay mark ZM. Therefore, the overlay mark ZM is formed while forming the plurality of oxide layers 108 and 208, instead of through an etching process. The plurality of oxide layers 108 and 208 may have round base angles θ1 and θ2.

Referring to FIG. 2, from a top view, the plurality of oxide layers 108 on the overlay mark ZM may have a V-shaped contour, but the embodiment of the present disclosure is not limited thereto. In some embodiments, the plurality of oxide layers 108 may have the same width W1. The plurality of oxide layers 108 may be spaced apart by equal distances D1. The width W1 may be less than, equal to, or greater than the distance D1.

Referring to FIG. 1C, a photoresist material (not shown) is formed on the substrate 100. Next, using the overlay mark ZM as the zero-layer overlay mark, a photoresist material is subjected to a photolithography process to form a photoresist layer PR1 having a plurality of openings OP3. The opening OP3 exposes the substrate 100 in the regions R2 and R3. Next, using the photoresist layer PR1 as an ion implantation mask, an ion implantation process P1 is performed to form doping regions 112 and 113 in the substrate 100 in the regions R2 and R3. The doping regions 112 and 113 are, for example, second conductivity type well regions.

Referring to FIG. 1D, the photoresist layer PR1 is removed. Next, a photoresist material (not shown) is formed on the substrate 100. Thereafter, using the overlay mark ZM as the zero-layer overlay mark, a photolithography process is performed on the photoresist material to form a photoresist layer PR2 having a plurality of openings OP4. The opening OP4 exposes the substrate 100 in the region R4. Then, using the photoresist layer PR2 as an ion implantation mask, an ion implantation process P2 is performed to form the doping region 114 in the substrate 100 in the region R4. The doping region 114 is, for example, a first conductive type well region.

Referring to FIG. 1E, the photoresist layer PR2 and the mask layer HM1 are removed, and the oxide layers 108 and 208 are removed. The oxide layer 108 in the region R1 is removed to expose the surfaces 100a and 100a′ of the substrate 100 and a plurality of grooves 110. The surface 100b of the substrate 100 is exposed after the oxide layer 208 in the region R2 is removed. The surface 100c of the substrate 100 is exposed after the mask layer HM1 in the region R3 is removed. The surface 100d of the substrate 100 is exposed after the mask layer HM1 in the region R4 is removed.

The height of the surface 100b of the substrate 100 in the region R2 is substantially equal to the height of the surface 100a′ of the substrate 100 in the region R1, and is lower than the heights of the surfaces 100a, 100c and 100d of the substrate 100 in the regions R1, R3 and R4.

Next, a mask layer HM2 is formed on the substrate 100. The mask layer HM2 includes a pad oxide layer 122 and a silicon nitride layer 124. The pad oxide layer 122 is formed on the substrate 100. A silicon nitride layer 124 is formed on the pad oxide layer 122. The pad oxide layer 122 is, for example, silicon oxide, and is formed by, for example, thermal oxidation. The silicon nitride layer 124 is formed by, for example, chemical vapor deposition.

Referring to FIG. 1F, a photoresist material is formed on the substrate 100. Next, using the overlay mark ZM as the zero-layer overlay mark, a photolithography process is performed on the photoresist material to form a photoresist layer PR3 having a plurality of openings OP5.

Afterwards, an etching process is performed to transfer the pattern of the photoresist layer PR3 to the mask layer HM2, and the substrate 100 is etched to form a plurality of trenches OP6. Afterwards, the photoresist layer PR3 is removed. The photoresist layer PR3 may also be removed before the substrate 100 is etched.

Referring to FIG. 1G, an insulating material (not shown) is formed on the mask layer HM2. Insulating materials may be single or multiple layers. Insulating materials include silicon oxide, silicon nitride, or combinations thereof. Afterwards, a chemical mechanical polishing process is performed using the mask layer HM2 as a stop layer to remove the insulating material on the mask layer HM2 and form an isolation structure 126 in the trench OP6.

Then, the mask layer HM2 is removed. Next, metal oxide semiconductor devices M2 and M3 are formed in the regions R2 and R3 respectively, and a metal oxide semi-device (not shown) is formed in the region R4. The metal oxide semiconductor device M2 in the region R2 is, for example, a second conductivity type medium voltage device (MVP for short). The metal oxide semiconductor device M3 in the region R3 is, for example, a second conductivity type low voltage device (LVP for short) or a second conductivity type high voltage device (HVP for short). The metal oxide semiconductor device (not shown) in the region R4 is, for example, a first conductivity type high voltage device (HVN for short).

While the gate dielectric layer 228 of the metal oxide semiconductor device M2 is formed in the region R2, the dielectric layer 128 may be formed in the groove 100 of the region R1. Therefore, the dielectric layer 128 may be formed of the same material as the gate dielectric layer 228.

The overlay mark ZM in an embodiment of the present disclosure is formed while the oxide layers 108 and 208 are formed. The oxide layer 208 will be subsequently removed, so that the surface 100b of the substrate 100 in the region R2 is lower than the surfaces 100c and 100d of the substrate 100 in other regions (e.g., regions R3 and R4). In other words, before forming the oxide layers 108 and 208, the substrate 100 does not undergo an additional etching process to form the groove 110 of the overlay mark ZM. The overlay mark ZM in an embodiment of the present disclosure may be used as a zero-layer overlay mark for implanting the mask in the subsequent implantation process. The overlay mark ZM may also be used as a zero-layer overlay mark forming the mask layer HM2 of the isolation structure 126.

The zero-layer overlay mark in the embodiment of the present disclosure may be formed simultaneously during the process of forming the metal oxide semiconductor device without the need for an additional etching process. Therefore, the present disclosure may be integrated with existing manufacturing processes, and may save steps of process, reduce costs, shorten cycle time, and improve yields.

What is claimed is:

1. A method of forming a zero-layer overlay mark, comprising:
forming a mask layer on a substrate;
patterning the mask layer to form a plurality of openings exposing the substrate; and
performing a thermal oxidation process to oxidize the substrate exposed by the plurality of openings to form a plurality of oxide layers, wherein a thickness of the substrate under the plurality of oxide layers is less than a thickness of the substrate under the mask layer, thereby forming a zero-layer overlay mark.

2. The method of forming the zero-layer overlay mark according to claim 1, wherein the mask layer comprises:
a pad oxide layer disposed on the substrate; and
a silicon nitride layer disposed on the pad oxide layer.

3. The method of forming the zero-layer overlay mark according to claim 1, wherein the zero-layer overlay mark is formed in a cutting lane region of the substrate.

4. A method of forming a semiconductor device, comprising:
providing a substrate, wherein the substrate comprises a chip region and a cutting lane region;
forming a mask layer on the substrate;
patterning the mask layer to form a plurality of first openings exposing the substrate in the cutting lane region, and form a second opening exposing the substrate in the chip region;
performing a thermal oxidation process to oxidize the substrate exposed by the plurality of first openings to form a plurality of first oxide layers, and to oxidize the substrate exposed by the second opening to form a second oxide layer, wherein a thickness of the substrate under the plurality of first oxide layers is less than a thickness of the substrate under the mask layer to form an overlay mark; and
using the overlay mark as a zero-layer overlay mark to perform a plurality of ion implantation processes on the substrate in the chip region.

5. The method of forming the semiconductor device according to claim 4, wherein the plurality of ion implantation processes comprise:
using the overlay mark as the zero-layer overlay mark, and forming a first ion implantation mask in the substrate;
forming a first conductivity type well region in the substrate in the chip region;
removing the first ion implantation mask;
using the overlay mark as the zero-layer overlay mark, and forming a second ion implantation mask in the substrate;
forming a second conductivity type well region in the substrate in the chip region; and
removing the second ion implantation mask.

6. The method of forming the semiconductor device according to claim 4, wherein the mask layer comprises:
a pad oxide layer disposed on the substrate; and
a silicon nitride layer disposed on the pad oxide layer.

7. The method of forming the semiconductor device according to claim 4, further comprising:
removing the patterned mask layer, the plurality of first oxide layers and the second oxide layer; and
using the overlay mark as the zero-layer overlay mark, and forming an isolation structure in the substrate in the chip region.

8. The method of forming the semiconductor device according to claim 7, further comprising:
forming a metal oxide semiconductor device on the substrate in the chip region.

9. The method of forming the semiconductor device according to claim 4, wherein the plurality of first openings and the second opening are formed through a same lithography process and a same etching process.

10. A zero-layer overlay mark, comprising:
a mask layer disposed on a substrate, wherein the mask layer has a plurality of openings exposing the substrate; and
a plurality of oxide layers located in the plurality of openings and extending into the substrate, wherein a thickness of the substrate under the plurality of oxide layers is less than a thickness of the substrate under the mask layer, thereby forming the zero-layer overlay mark.

11. The zero-layer overlay mark according to claim 10, wherein the mask layer comprises:
a pad oxide layer disposed on the substrate; and
a silicon nitride layer disposed on the pad oxide layer.

12. The zero-layer overlay mark according to claim 11, wherein a thickness of the plurality of oxide layers is greater than a thickness of the pad oxide layer.

13. The zero-layer overlay mark according to claim 11, wherein a plurality of top surfaces of the plurality of oxide layers are higher than a top surface of the pad oxide layer, and a plurality of bottom surfaces of the plurality of oxide layers are lower than a bottom surface of the pad oxide layer.

14. The zero-layer overlay mark according to claim 11, wherein a plurality of top surfaces of the plurality of oxide layers are higher than a bottom surface of the silicon nitride layer, and the plurality of top surfaces of the plurality of oxide layers are lower than a top surface of the silicon nitride layer.

15. The zero-layer overlay mark according to claim 11, wherein the plurality of oxide layers are in contact with a sidewall of the pad oxide layer and a part of a sidewall of the silicon nitride layer.

16. The zero-layer overlay mark according to claim 15, wherein another part of the sidewall of the silicon nitride layer adjacent to the plurality of oxide layers is not covered by the plurality of oxide layers.

17. The zero-layer overlay mark according to claim 10, wherein the plurality of oxide layers have a V-shaped contour.

18. The zero-layer overlay mark according to claim 10, wherein the plurality of oxide layers have equal widths.

19. The zero-layer overlay mark according to claim 18, wherein the plurality of oxide layers are spaced apart by equal distances.

20. The zero-layer overlay mark according to claim 19, wherein the distances between the plurality of oxide layers are equal to the width.
